(19) United States
(12) Patent Application Publication
(10) Pub. No.: US 2017/0170212 A1
(43) Pub. Date: Jun. 15, 2017

(54) THIN FILM TRANSISTOR ARRAY SUBSTRATE AND METHOD OF FABRICATING THE SAME

(71) Applicant: SHENZHEN CHINA STAR OPTOELECTRONICS TECHNOLOGY CO., LTD., Shenzhen, Guangdong (CN)

(72) Inventor: Qiming GAN, Shenzhen, Guangdong (CN)

(21) Appl. No.: 14/773,342

(22) PCT Filed: Jul. 29, 2015
(86) PCT No.: PCT/CN2015/085379

§ 371 Date: Sep. 6, 2015

(30) Foreign Application Priority Data
Jul. 10, 2015 (CN) 201510406144.1

(51) Int. Cl. H01L 27/12

(52) U.S. Cl. CPC H01L 27/1288; H01L 27/1248; G02F 1/1368

(57) ABSTRACT

A thin film transistor array substrate and a method of fabricating the same are disclosed. The thin film transistor array substrate has a device lamination layer, a passivation layer and a pixel electrode layer; the device lamination layer has a substrate, a first signal line layer, a semiconductor layer and a second signal line layer; the passivation layer is formed with a through hole and grooves; the pixel electrode layer is disposed on the passivation layer and inside the grooves; and the pixel electrode layer is connected with the second signal line layer through the through hole. The fabricating cost can be saved and the fabricating efficiency can be improved.

### FIELD OF THE INVENTION

The present invention relates to a display technology, and more particularly to a thin film transistor array substrate and a method of fabricating the same.

### BACKGROUND OF THE INVENTION

A fabricating process of a traditional thin film transistor array substrate generally is required to dispose a through hole and a groove in a passivation layer, and to dispose a pixel electrode layer on a surface of the passivation layer and inside the groove, in which the pixel electrode layer is connected with a data line layer in the thin film transistor array substrate through the through hole.

In the traditional technical solution described above, disposing the through hole in the passivation layer and disposing the groove in the passivation layer are performed separately, in other words, disposing the through hole in the passivation layer and disposing the groove in the passivation layer are two independent steps.

For the two independent steps described above, two different Normal Mask mask-process required suffer from a higher cost on the technical solution described above and cause that a fabricating efficiency of the thin-film transistor array substrate is not high.

Therefore, it is necessary to provide a new technical solution to solve the technical problem described above.

### SUMMARY OF THE INVENTION

A primary object of the present invention is to provide a thin film transistor array substrate and a method of fabricating the same, in which the fabricating cost of the thin film transistor array substrate can be saved and the fabricating efficiency of the thin film transistor array substrate can be improved.

In order to solve the problem described above, a technical solution of the present invention is disclosed as follows:

A thin film transistor array substrate comprises: a device lamination layer including: a substrate; a first signal line layer; a semiconductor layer; and a second signal line layer; a passivation layer disposed on the device lamination layer, and formed with a through hole and a groove array having at least one groove; a pixel electrode layer disposed on the passivation layer and inside the groove array, the pixel electrode layer connected with the second signal line layer through the through hole; in which the through hole has a first depth, and the groove has a second depth; in which the groove array and the through hole are formed by an identical mask process and an identical etching process; in which the device lamination layer further includes a first insulating layer, a second insulating layer and a drain line layer; in which the first signal line layer is a scanning line layer, the semiconductor layer is an amorphous silicon layer or a polysilicon layer, and the second signal line layer is a data line layer; in which when the semiconductor layer is the amorphous silicon layer, the scanning line layer is disposed below the amorphous silicon layer, the first insulating layer is disposed between the scanning line layer and the amorphous silicon layer, the second insulating layer is disposed above the amorphous silicon layer, the data line layer is disposed above the second insulating layer, and the data line layer passes through the second insulating layer to be connected with the amorphous silicon layer; and in which when the semiconductor layer is the polysilicon layer, the scanning line layer is disposed above the polysilicon layer, the first insulating layer is disposed between the polysilicon layer and the scanning line layer, the second insulating layer is disposed above the scanning layer, the data line layer is disposed above the second insulating layer, and the data line layer passes through the first insulting layer to be connected with the polysilicon layer.

In the thin film transistor array substrate described above, a mask corresponding to the mask process comprises: a first region having a first transmittance and corresponding to the through hole, in which the first transmittance is corresponding to the first depth; and at least one second region having a second transmittance and corresponding to the groove, in which the second transmittance is corresponding to the second depth.

In the thin film transistor array substrate described above, the mask is a half tone mask.

In the thin film transistor array substrate described above, the first transmittance is 100%, and the second transmittance is ranged from 0% to 100%.

In the thin film transistor array substrate described above, the second transmittance is ranged from 13% to 91%.

In the thin film transistor array substrate described above, he groove array and the through hole are formed by performing the mask process to a photoresist material layer on the passivation layer to form a first recess and a second recess respectively on a third region and a fourth region of the photoresist material layer, and then etching the passivation layer and the photoresist material layer at the first recess and the second recess; and in which the third region is corresponding to the first region, the fourth region is corresponding to the second region, the first recess has a third depth, and the second recess has a fourth depth.

A thin film transistor array substrate comprises: a device lamination layer including: a substrate; a first signal line layer; a semiconductor layer; and a second signal line layer; a passivation layer disposed on the device lamination layer, and formed with a through hole and a groove array having at least one groove; and a pixel electrode layer disposed on the passivation layer and inside the groove array, in which the pixel electrode layer is connected with the second signal line layer through the through hole.

In the thin film transistor array substrate described above, the through hole has a first depth and the groove has a second depth; and in which the groove array and the through hole are formed by an identical mask process and an identical etching process.

In the thin film transistor array substrate described above, a mask corresponding to the mask process comprises: a first region having a first transmittance and corresponding to the through hole, in which the first transmittance is corresponding to the first depth; and at least one second region having a second transmittance and corresponding to the groove, in which the second transmittance is corresponding to the second depth.

In the thin film transistor array substrate described above, the mask is a half tone mask.

In the thin film transistor array substrate described above, the first transmittance is 100%, and the second transmittance is ranged from 0% to 100%.

In the thin film transistor array substrate described above, the second transmittance is ranged from 13% to 91%.

In the thin film transistor array substrate described above, the groove array and the through hole are formed by performing the mask process to a photoresist material layer on the passivation layer to form a first recess and a second recess respectively on a third region and a fourth region of the photoresist material layer, and then etching the passivation layer and the photoresist material layer at the first recess and the second recess; and in which the third region is corresponding to the first region, the fourth region is corresponding to the second region, the first recess has a third depth, and the second recess has a fourth depth.

A method of fabricating the thin film transistor array substrate described above comprises the following steps of: (A) forming the device lamination layer, in which the thin film transistor array includes a substrate, a first signal line layer, a semiconductor layer and a second signal line layer; (B) disposing the passivation layer on the device lamination layer; (C) performing a mask process and an etching process to the passivation layer for forming a through hole and a groove array in a surface of the passivation layer, in which the groove array has at least one groove; and (D) disposing a pixel electrode layer on the surface and inside the groove array of the passivation layer, in which the pixel electrode layer is connected with the second signal line layer through the through hole.

In the method of fabricating the thin film transistor array substrate described above, the through hole has a first depth and the groove has the second groove; and in which the step (C) includes the following step of: (C1) forming the groove array and the through hole by performing the same mask process and the same etching process on the passivation layer.

In the method of fabricating the thin film transistor array substrate described above, a mask corresponding to the mask process comprises: a first region having a first transmittance and corresponding to the through hole, in which the first transmittance is corresponding to the first depth; and at least one second region having a second transmittance and corresponding to the groove, in which the second transmittance is corresponding to the second depth.

In the method of fabricating the thin film transistor array substrate described above, the mask is a half tone mask.

In the method of fabricating the thin film transistor array substrate described above, the first transmittance is 100%, and the second transmittance is ranged from 0% to 100%.

In the method of fabricating the thin film transistor array substrate described above, the second transmittance is ranged from 13% to 91%.

In the method of fabricating the thin film transistor array substrate described above, the step (C1) comprises the following steps of: (C11) disposing a photoresist material layer on the passivation layer; (C12) performing the mask process to the photoresist material layer, so as to form a first recess and a second recess respectively on a third region and a fourth region on the photoresist layer, in which the third region is corresponding to the first region, the fourth region is corresponding to the second region, the first recess has a third depth, and the second recess has a fourth depth; and (C13) etching the passivation layer and the photoresist material layer at the first recess and the second recess, so as to form the groove array and the through hole in the passivation layer.

With respect to the prior art, the present invention may save a mask process, which is benefit of saving the fabricating cost of the thin film transistor array substrate and improving the fabricating efficiency of the thin film transistor array substrate.

To make the above description of the present invention can be more clearly comprehensible, description below in examples of preferred embodiments with the accompanying drawings, described in detail below.

### DESCRIPTION OF THE DRAWINGS

FIG. 1 to FIG. 6 are schematic diagrams of a method of fabricating a thin film transistor array substrate in accordance with a first embodiment of the present invention;

FIG. 6 is a schematic diagram of a thin film transistor array substrate in accordance with the present invention;

FIG. 7 is a schematic diagram of a mask used in a fabricating process of the thin film transistor array substrate showed in FIG. 1 to FIG. 6;

FIG. 8 is a flow chart of a method of fabricating a thin film transistor array substrate in accordance with a first embodiment of the present invention;

FIG. 9 is a flow chart of a method of fabricating a thin film transistor array substrate in accordance with a second embodiment of the present invention; and

FIG. 10 is a flow chart of a method of fabricating a thin film transistor array substrate in accordance with a third embodiment of the present invention.

### DETAILED DESCRIPTION OF THE PREFERRED EMBODIMENTS

As used in this specification, the term “embodiment” means that an instance, an example or illustration. In addition, the articles in this specification and the appended claims, use of “a”, in general can be interpreted as “one or more than one” unless specified otherwise or being clear from context to determine the singular form.

A display of the present invention may be a thin film transistor liquid crystal display (TFT-LCD).

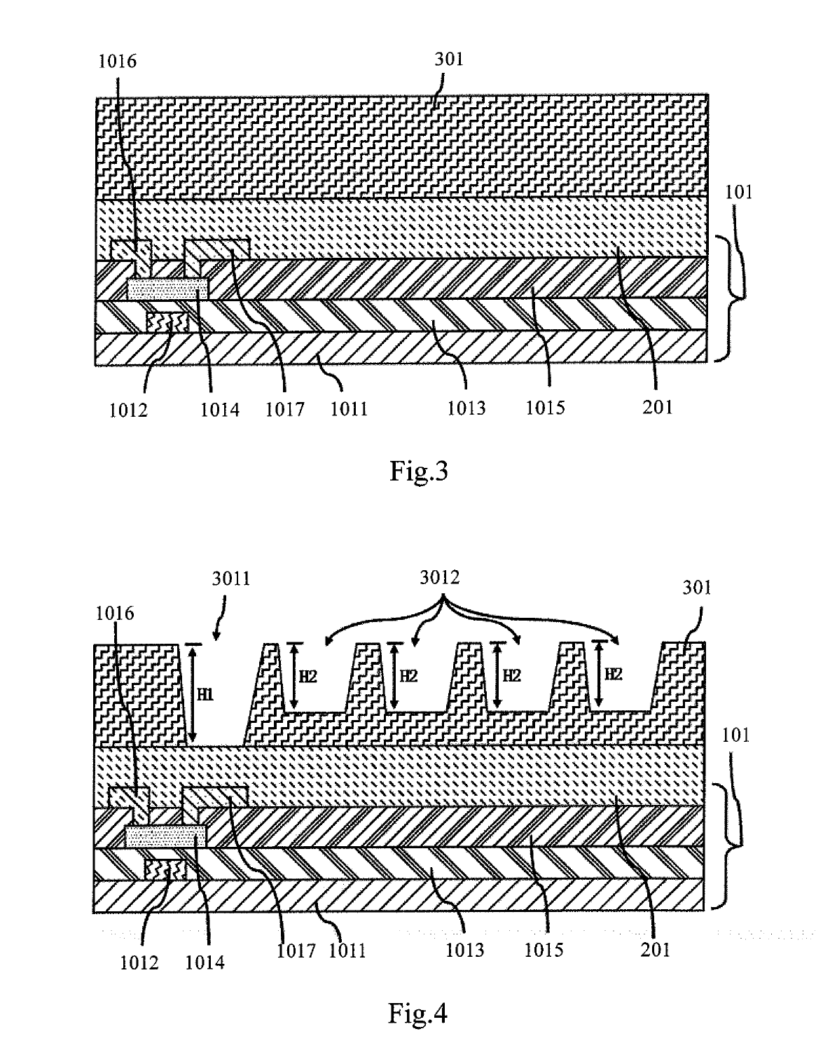

Referring to FIG. 6, FIG. 6 is a diagram of a thin film transistor array substrate in accordance with the present invention.

A thin film transistor array substrate of the present invention includes a device lamination layer 101, a passivation layer 201 and a pixel electrode layer 601

The device lamination layer 101 includes a substrate 1011, a first signal line layer 1012, a semiconductor layer 1014 and a second signal line layer 1017. The device lamination layer 101 further includes a first insulating layer 1013, a second insulating layer 1015 and a drain line layer 1016.

The first signal line layer 1012 may be a scanning line layer, the semiconductor layer 1014 may be an amorphous silicon layer or a polysilicon layer, and the second signal line layer 1017 may be a data line layer. The scanning line layer is disposed below the semiconductor layer 1014 (the semiconductor layer is the amorphous silicon layer), the first insulating layer 1013 is disposed between the scanning line layer and the amorphous silicon layer, the second insulating layer is disposed above the amorphous silicon layer, the data line layer is disposed above the second insulating layer, and the data line layer passes through the second insulating layer 1015 to be connected with the amorphous silicon layer; or, the scanning line layer is disposed above the polysilicon layer 1014 (the polysilicon layer 1014 is the polysilicon layer), the first insulating layer 1013 is disposed between the polysilicon layer and the scanning line layer, the second insulating layer 1015 is disposed above the scanning layer, the data line layer is disposed above the second insulating layer 1015, and the data line layer passes through the first insulating layer 1013 and the second insulating layer 1015 to be connected with the polysilicon layer.

The passivation layer 201 is disposed on the device lamination layer 101 and is formed with a through hole 2011 and a groove array 2012 having at least one groove 20121. The pixel electrode layer 601 is disposed on the passivation layer 201 and inside the groove array 2012, and is connected with the second signal line layer 1017 through the through hole 2011.

In this embodiment, the through hole 2011 has a first depth H3, and the groove 20121 has a second depth H4. Both the groove array 2012 and the through hole 2011 are formed by performing the same mask process and the same etching process. In other words, both the groove array 2012 and the through hole 2011 are formed in the same mask process.

In comparison with a traditional technical solution, a mask process (Normal process) may be saved in the above technical solution for saving the fabricating cost of the thin film transistor array substrate and improving the fabricating efficiency of the thin film transistor array substrate.

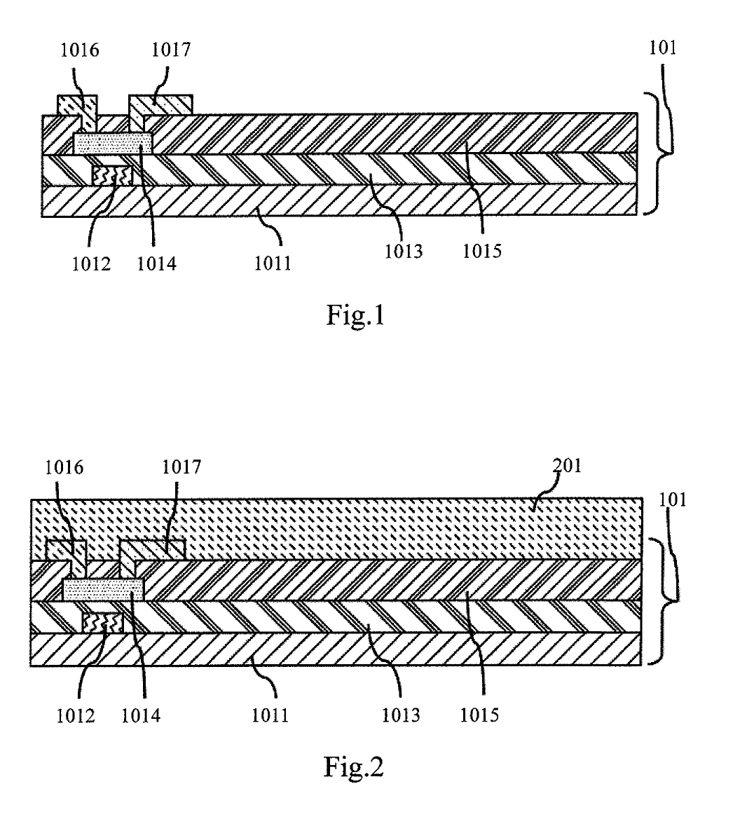

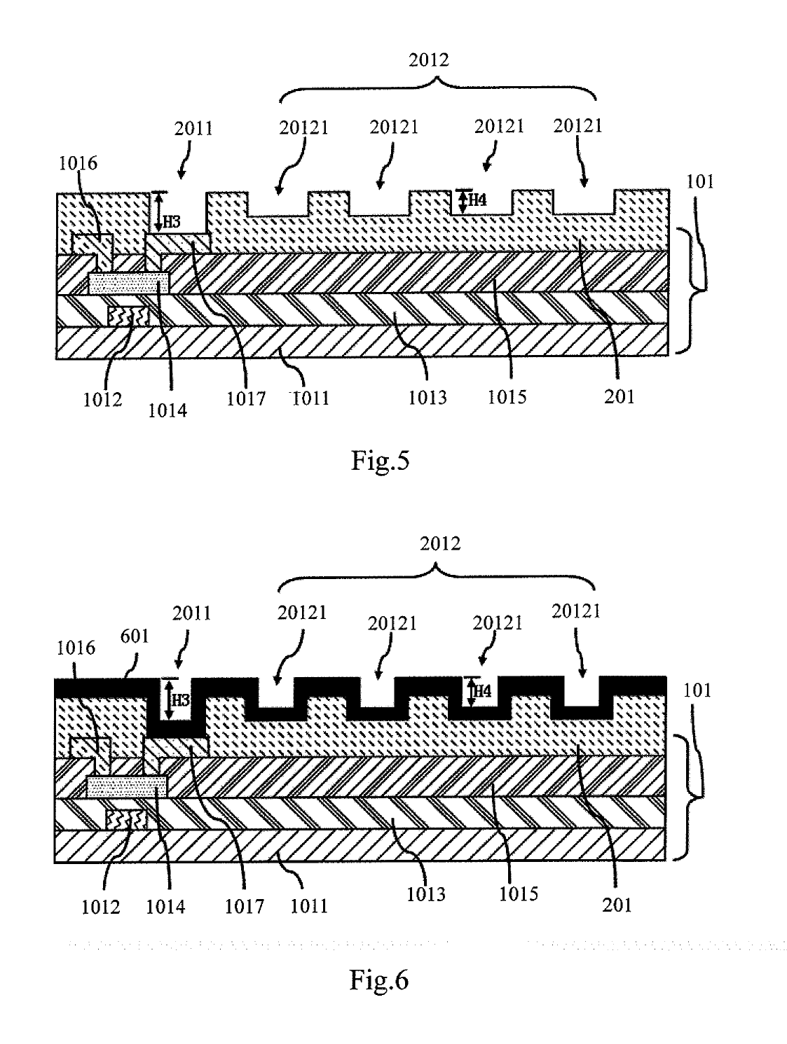

Referring to FIG. 7, FIG. 7 is a schematic diagram of a mask used in a fabricating process of the thin film transistor array substrate showed in FIG. 1 to FIG. 6.

In this embodiment, a mask 701 corresponding to the mask process includes a first region 7011 and a second region 7012. The first region 7011 has a first transmittance and is corresponding to the through hole 2011, in which the first transmittance is corresponding to the first depth H3. The second region 7012 has a second transmittance and is corresponding to the groove 20121, in which the second transmittance is corresponding to the second depth H4.

Preferably, in the present embodiment, the mask 701 is a half tone mask (HTM).

A depth of the through hole 2011 (the first depth H3) and a depth of the groove 20121 (the second depth H4) may be disposed according to a transmittance of the HTM (open interval ranged from 0% to 100%).

In other words, the first depth H3 and the second depth H4 of the passivation layer 201 are formed by such a method:

Performing the mask process to the passivation layer 201 by using the mask with the first region 7011 and the second region 7012 for forming the first depth H3 and the second depth H4 simultaneously, in which the first region 7011 has a first transmittance and the second region 7012 has a second transmittance. For example, the first transmittance is 100%, and the second transmittance (a%) is ranged from 0% to 100% (open interval), e.g. the a% is 0.5%, 1%, 3%, 5%, 7%, 9%, 11%, 13%, 15%, 17%, 19%, 21%, 23%, 25%, 27%, 29%, 31%, 33%, 35%, 37%, 39%, 41%, 43%, 45%, 47%, 49%, 51%, 53%, 55%, 57%, 59%, 61%, 63%, 65%, 67%, 69%, 71%, 73%, 75%, 77%, 79%, 81%, 83%, 85%, 87%, 89%, 91%, 93%, 95%, 97%, 99%.

As shown in FIG. 1 to FIG. 6, in the present invention, the groove array 2012 and the through hole 2011 are formed by performing the mask process to a photoresist material layer 301 on the passivation layer 201 to form a first recess 3011 and a second recess 3012 respectively on a third region and a fourth region on the photoresist material layer 301, and etching the passivation layer 201 and the photoresist material layer 301 at the first recess 3011 and the second recess 3012.

In which the third region is corresponding to the first region 7011, the fourth region is corresponding to the second region 7012, the first recess 3011 has a third depth H1, and the second recess 3012 has a fourth depth H2.

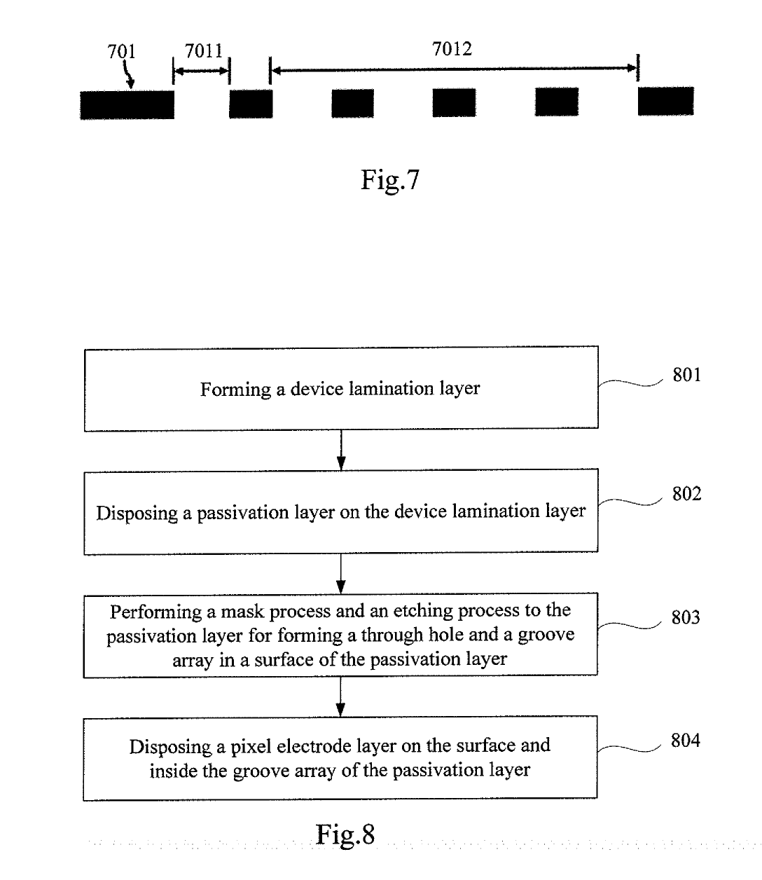

Referring to FIG. 1 to FIG. 6 and FIG. 8, FIG. 1 to FIG. 6 are schematic diagrams of a method of fabricating a thin film transistor array substrate in accordance with a first embodiment of the present invention and FIG. 8 is a flow chart of a method of fabricating a thin film transistor array substrate in accordance with a first embodiment of the present invention.

The method of fabricating the thin film transistor array substrate of the present invention includes the following steps of:

(A) (step 801) forming the device lamination layer 101, in which the thin film transistor array 101 includes a substrate 1011, a first signal line layer 1012, a semiconductor layer 1014 and a second signal line layer 1017;

(B) (step 802) disposing the passivation layer 201 on the device lamination layer 101;

(C) (step 803) performing a mask process and an etching process to the passivation layer 201 for forming a through hole 2011 and a groove array 2012 in a surface of the passivation layer 201, in which the groove array 2012 has at least one groove 20121; and

(D) (step 804) disposing a pixel electrode layer 601 on the surface and inside the groove array 2012 of the passivation layer 201, in which the pixel electrode layer 601 is connected with the second signal line layer 1017 through the through hole 2011.

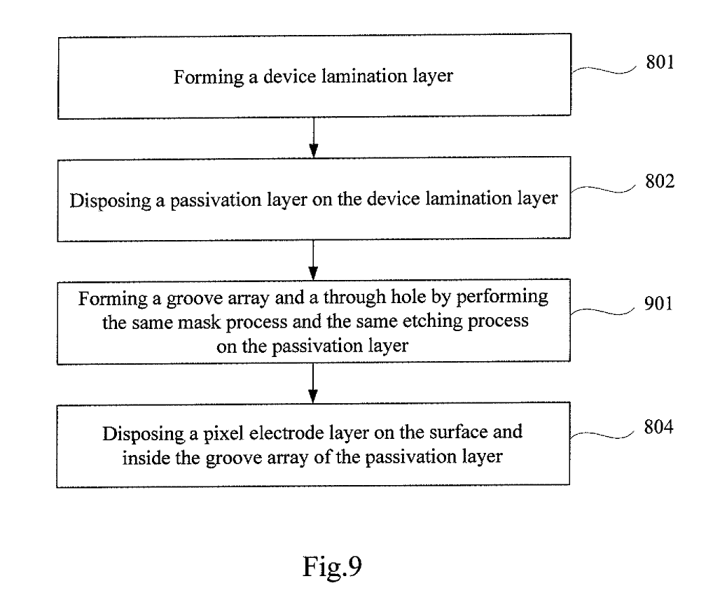

Referring to FIG. 9, FIG. 9 is a flow chart of a method of fabricating a thin film transistor array substrate in accordance with a second embodiment of the present invention. The present embodiment is similar to the above first embodiment, except that:

in the present embodiment, the through hole 2011 has a first depth H3, and the groove 20121 has a second depth H4. In other words, the through hole 2011 is different from the groove 20121 in depth, and the through hole 2011 and the groove 20121 with different depths are formed in the same mask process and the same etching process. It means that the step (C) (which means the step 803) includes the following step of:

(C1) (step 901) forming the groove array 2012 and the through hole 2011 by performing the same mask process and the same etching process to the passivation layer 201.

In comparison with a traditional technical solution, a mask process (Normal process) may be saved in the above technical solution for saving the fabricating cost of the thin film transistor array substrate and improving the fabricating efficiency of the thin film transistor array substrate.

In the present embodiment, a mask 701 corresponding to the mask process includes a first region 7011 and a second region 7012. The first region 7011 has a first transmittance and is corresponding to the through hole 2011, in which the first transmittance is corresponding to the first depth H3. The second region 7012 has a second transmittance and is corresponding to the groove 20121, in which the second transmittance is corresponding to the second depth H4.

Preferably, in the present embodiment, the mask 701 is a half tone mask.

A depth of the through hole 2011 (the first depth H3) and a depth of the groove 20121 (the second depth H4) may be disposed according to a transmittance of the HTM (open interval ranged from 0% to 100%).

In other words, the first depth H3 and the second depth H4 of the passivation layer 201 are formed by such a method:

Performing the mask process to the passivation layer 201 by using the mask with the first region 7011 and the second region 7012 for forming the first depth H3 and the second depth H4 simultaneously, in which the first region 7011 has a first transmittance and the second region 7012 has a second transmittance. For example, the first transmittance is 100%, and the second transmittance (a%) is ranged from 0% to 100% (open interval), e.g. the a% is 0.5%, 1%, 3%, 5%, 7%, 9%, 11%, 13%, 15%, 17%, 19%, 21%, 23%, 25%, 27%, 29%, 31%, 33%, 35%, 37%, 39%, 41%, 43%, 45%, 47%, 49%, 51%, 53%, 55%, 57%, 59%, 61%, 63%, 65%, 67%, 69%, 71%, 73%, 75%, 77%, 79%, 81%, 83%, 85%, 87%, 89%, 91%, 93%, 95%, 97%, 99%.

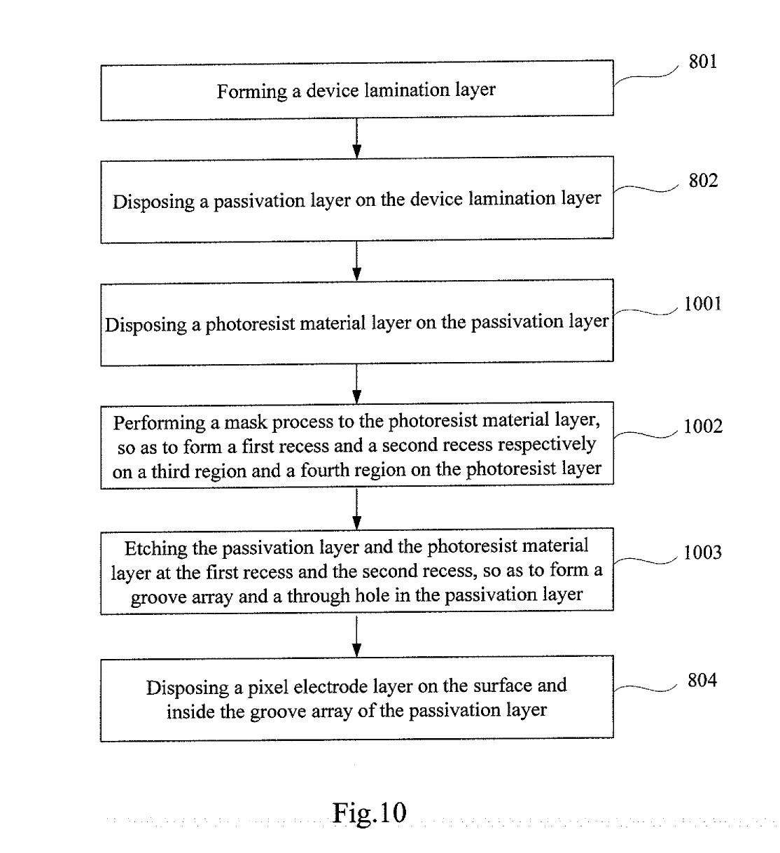

Referring to FIG. 10, FIG. 10 is a flow chart of a method of fabricating a thin film transistor array substrate in accordance with a third embodiment of the present invention. The present embodiment is similar to the above second embodiment, except that:

in the present embodiment, the step (C1) (which means the step 901) includes the following steps of:

(C11) (step 1001) disposing a photoresist material layer 301 on the passivation layer 201;

(C12) (step 1002) performing the mask process to the photoresist material layer 301, so as to form a first recess 3011 and a second recess 3012 respectively on a third region and a fourth region on the photoresist material layer 301, in which the third region is corresponding to the first region 7011, the fourth region is corresponding to the second region 7012, the first recess 3011 has a third depth H1, and the second recess 3012 has a fourth depth H2; and

(C13) (step 1003) etching the passivation layer 201 and the photoresist material layer 301 at the first recess 3011 and the second recess 3012, so as to form the groove array 2012 and the through hole 2011 in the passivation layer 201.

Despite relative to one or more implementations shown and described the present invention, those skilled in the art based on the specification and drawings of reading and understanding would expect equivalent variations and modifications. The present invention includes all such modifications and variations, and is only limited by the scope of the appended claims. Particularly with regard to the various functions performed by the above-described components, the terms used to describe such components are intended to perform any component (unless otherwise indicated) which is corresponding to the specified function (e.g., those are functionally equivalent) of the component, even those in structure not equivalent to performing public structures of functions of exemplary embodiments in the present specification shown in the context. In addition, although a particular feature of this specification with respect to only one in a number of implementations is open, but this feature can be combined with which, e.g., one or more other features of other desirable and advantageous embodiments in terms of being given or specific applications. Furthermore, with regard to the terms “include”, “have”, “contain” or variations thereof used in the detailed description or the claims, such a term is intended to include the term “comprise” in similar manner,

According to the above, although the present invention has been described in a preferred embodiment described above, preferred embodiments described above are not intended to limit the invention, one of ordinary skill in the art without departing from the spirit and scope of the invention within, can make various modifications and variations, so the range of the scope of the invention defined by the claims prevail.

What is claimed is:

1. A thin film transistor array substrate, comprising:
a device lamination layer including:
a substrate;
a first signal line layer;
a semiconductor layer; and
a second signal line layer;
a passivation layer disposed on the device lamination layer, and formed with a through hole and a groove array having at least one groove;
a pixel electrode layer disposed on the passivation layer and inside the groove array, the pixel electrode layer connected with the second signal line layer through the through hole;
wherein the through hole has a first depth, and the groove has a second depth;
wherein the groove array and the through hole are formed by an identical mask process and an identical etching process;
wherein the device lamination layer further includes a first insulating layer, a second insulating layer and a drain line layer;
wherein the first signal line layer is a scanning line layer, the semiconductor layer is an amorphous silicon layer or a polysilicon layer, and the second signal line layer is a data line layer;
wherein when the semiconductor layer is the amorphous silicon layer, the scanning line layer is disposed below the amorphous silicon layer, the first insulating layer is disposed between the scanning line layer and the amorphous silicon layer, the second insulating layer is disposed above the amorphous silicon layer, the data line layer is disposed above the second insulating layer, and the data line layer passes through the second insulating layer to be connected with the amorphous silicon layer; and
wherein when the semiconductor layer is the polysilicon layer, the scanning line layer is disposed above the polysilicon layer, the first insulating layer is disposed between the polysilicon layer and the scanning line layer, the second insulating layer is disposed above the scanning layer, the data line layer is disposed above the second insulating layer, and the data line layer passes through the first insulting layer to be connected with the polysilicon layer.

2. The thin film transistor array substrate according to claim 1, wherein a mask corresponding to the mask process comprises:
a first region having a first transmittance and corresponding to the through hole, wherein the first transmittance is corresponding to the first depth; and
at least one second region having a second transmittance and corresponding to the groove, wherein the second transmittance is corresponding to the second depth.

3. The thin film transistor array substrate according to claim 2, wherein the mask is a half tone mask.

4. The thin film transistor array substrate according to claim 3, wherein the first transmittance is 100%, and the second transmittance is ranged from 0% to 100%.

5. The thin film transistor array substrate according to claim 4, wherein the second transmittance is ranged from 13% to 91%.

6. The thin film transistor array substrate according to claim 1, wherein the groove array and the through hole are formed by performing the mask process to a photoresist material layer on the passivation layer to form a first recess and a second recess respectively on a third region and a fourth region of the photoresist material layer, and then etching the passivation layer and the photoresist material layer at the first recess and the second recess; and
wherein the third region is corresponding to the first region, the fourth region is corresponding to the second region, the first recess has a third depth, and the second recess has a fourth depth.

7. A thin film transistor array substrate, comprising:
a device lamination layer including:
a substrate;
a first signal line layer;
a semiconductor layer; and
a second signal line layer;
a passivation layer disposed on the device lamination layer, and formed with a through hole and a groove array having at least one groove; and
a pixel electrode layer disposed on the passivation layer and inside the groove array, wherein the pixel electrode layer is connected with the second signal line layer through the through hole.

8. The thin film transistor array substrate according to claim 7, wherein the through hole has a first depth and the groove has a second depth; and
wherein the groove array and the through hole are formed by an identical mask process and an identical etching process.

9. The thin film transistor array substrate according to claim 8, wherein a mask corresponding to the mask process comprises:
a first region having a first transmittance and corresponding to the through hole, wherein the first transmittance is corresponding to the first depth; and
at least one second region having a second transmittance and corresponding to the groove, wherein the second transmittance is corresponding to the second depth.

10. The thin film transistor array substrate according to claim 9, wherein the mask is a half tone mask.

10. thin film transistor array substrate according to claim 10, wherein the first transmittance is 100%, and the second transmittance is ranged from 0% to 100%.

12. The thin film transistor array substrate according to claim 11, wherein the second transmittance is ranged from 13% to 91%.

13. The thin film transistor array substrate according to claim 8, wherein the groove array and the through hole are formed by performing the mask process to a photoresist material layer on the passivation layer to form a first recess and a second recess respectively on a third region and a fourth region of the photoresist material layer, and then etching the passivation layer and the photoresist material layer at the first recess and the second recess; and
wherein the third region is corresponding to the first region, the fourth region is corresponding to the second region, the first recess has a third depth, and the second recess has a fourth depth.

14. A method of fabricating a thin film transistor array substrate as claimed in claim 7, comprising the following steps of:
(A) forming the device lamination layer, wherein the thin film transistor array includes a substrate, a first signal line layer, a semiconductor layer and a second signal line layer;
(B) disposing the passivation layer on the device lamination layer;
(C) performing a mask process and an etching process to the passivation layer for forming a through hole and a groove array in a surface of the passivation layer, wherein the groove array has at least one groove; and
(D) disposing a pixel electrode layer on the surface and inside the groove array of the passivation layer, wherein the pixel electrode layer is connected with the second signal line layer through the through hole.

15. The method of fabricating the thin film transistor array substrate according to claim 14, wherein the through hole has a first depth and the groove has the second groove; and
wherein the step (C) includes the following step of:
(C1) forming the groove array and the through hole by performing the same mask process and the same etching process to the passivation layer.

16. The method of fabricating the thin film transistor array substrate according to claim 15, wherein a mask corresponding to the mask process comprises:
a first region having a first transmittance and corresponding to the through hole, wherein the first transmittance is corresponding to the first depth; and
at least one second region having a second transmittance and corresponding to the groove, wherein the second transmittance is corresponding to the second depth.

17. The method of fabricating the thin film transistor array substrate according to claim 16, wherein the mask is a half tone mask.

18. The method of fabricating the thin film transistor array substrate according to claim 17, wherein the first transmittance is 100%, and the second transmittance is ranged from 0% to 100%.

19. The method of fabricating the thin film transistor array substrate according to claim 18, wherein the second transmittance is ranged from 13% to 91%.

20. The method of fabricating the thin film transistor array substrate according to claim 15, wherein the step (C1) comprises the following steps of:
(C11) disposing a photoresist material layer on the passivation layer;
(C12) performing the mask process to the photoresist material layer, so as to form a first recess and a second recess respectively on a third region and a fourth region on the photoresist material layer, wherein the third region is corresponding to the first region, the fourth region is corresponding to the second region, the first recess has a third depth, and the second recess has a fourth depth; and
(C13) etching the passivation layer and the photoresist material layer at the first recess and the second recess, so as to form the groove array and the through hole in the passivation layer.
